(19) United States
(12) Patent Application Publication
(10) Pub. No.: US 2026/0228399 A1
(43) Pub. Date: Aug. 6, 2026

(54) SIMULATION APPARATUS

(71) Applicant: FANUC CORPORATION, Yamanashi (JP)

(72) Inventor: Kouya YAMAMOTO, Yamanashi (JP)

(21) Appl. No.: 18/856,059

(22) PCT Filed: Apr. 20, 2022
(86) PCT No.: PCT/JP2022/018326

§ 371 Date: Oct. 11, 2024

(51) Int. Cl. G06F 30/28

(52) U.S. Cl. CPC G06F 30/28

(57) ABSTRACT

A simulation apparatus causes a three-dimensional model representing a robot to operate in a virtual space in accordance with an operation program for causing the robot to operate. The simulation apparatus includes a reception unit configured to receive an input of a parameter relating to the operation program, a physical quantity calculation unit configured to calculate, based on the parameter, a physical quantity applied to a reference point of the robot, and a display unit 4 configured to display the three-dimensional model and one visual element selected, based on the physical quantity, from a plurality of visual elements.

### RELATED APPLICATIONS

The present application is a National Phase of International Application No. PCT/JP2022/018326 filed Apr. 20, 2022.

### TECHNICAL FIELD

This disclosure relates generally to a simulation apparatus.

### BACKGROUND ART

As a method for teaching a predetermined operation to a robot, methods such as an on-line teaching method, an off-line teaching method have been proposed. For example, a teaching method based on a teaching playback method is known as an on-line teaching method. On the other hand, as an off-line teaching method, there is a teaching method based on a simulation method. Off-line teaching based on a simulation method is widely used because it can create three-dimensional models of a robot, an end effector, a workpiece, a peripheral device, and the like, and create an operation program while simulating the operation of the entire system in a virtual space displayed on a personal computer so that the actual machine need not be operated. In creating an operation program, physical quantities such as acceleration, speed, and shaking that occur at the robot, the end effector, the workpiece, and the like are sometimes important. In particular, if the workpiece is required to be kept horizontal, the tilt of the workpiece can be one of the important indicators. In addition, in the case where the strength of the workpiece is questionable, or the position of the center of gravity of the held workpiece is misaligned with the tool center position of the robot, the acceleration, which causes an inertial load on the workpiece, can be one of the important indicators. As described above, in the case where an operation program is created while simulating the operation of the robot system, it is important for the user to grasp the physical quantities that occur at the robot, the end effector, the workpiece, and the like. For example, a technique is known in which the acceleration of a robot apparatus is represented by a graph and is partly displayed in color depending on its magnitude (for example, Patent Literature 1).

However, even if physical quantities such as acceleration are displayed in a graph form or as numerical values, it is difficult for the user to grasp them intuitively.

### CITATION LIST

### Patent Literature

Patent Literature 1: Japanese Unexamined Patent Application Publication No. 2019-123052

### BRIEF DESCRIPTION OF THE DRAWINGS

FIG. 1 is a functional block diagram of a simulation apparatus according to the present embodiment.

FIG. 2 shows an example of a virtual space in a state in which a robot system model is arranged, which is displayed on a display unit of the simulation apparatus shown in FIG. 1.

FIG. 3 shows an example of a procedure for creating an operation program by the simulation apparatus shown in FIG. 1.

FIG. 4 is a flowchart showing an example of a procedure of a process of selecting an object shown in FIG. 3.

FIG. 5A to FIG. 5D show examples of four types of objects that are candidates for selection in FIG. 4.

FIG. 6 shows an example of a state in which objects are arranged in the virtual space shown in FIG. 2.

FIG. 7A and FIG. 7B show other forms of the objects in FIG. 5A to FIG. 5D.

FIG. 8A and FIG. 8B show other forms of the objects in FIG. 5A to FIG. 5D.

FIG. 9A and FIG. 9B show another example of the objects in FIG. 5A to FIG. 5D.

FIG. 10 shows another example of the state in which objects are arranged in the virtual space shown in FIG. 2.

### DETAILED DESCRIPTION

A simulation apparatus according to one aspect of the present disclosure is a simulation apparatus for causing a three-dimensional model representing a robot to operate in a virtual space in accordance with an operation program for causing the robot to operate, the simulation apparatus comprising: a reception unit configured to receive an input of a parameter relating to the operation program; a physical quantity calculation unit configured to calculate, based on the parameter, a physical quantity applied to a reference point of the robot; and a display unit configured to display the three-dimensional model and one visual element selected, based on the physical quantity, from a plurality of visual elements.

Hereinafter, a simulation apparatus according to the present embodiment will be described with reference to the drawings. In the following description, constituent elements having substantially the same function and configuration are denoted by the same reference numeral, and repetitive descriptions will be given only where necessary.

The simulation apparatus according to the present embodiment is a computer apparatus (information processing apparatus) having a function of simulating the operation of a robot model in a virtual space using software in accordance with an operation program for moving a robot. In particular, the simulation apparatus according to the present embodiment selectively uses different visual elements (pictorial diagrams) to allow the user to intuitively visually recognize the amount of a physical quantity such as acceleration applied to, for example, a hand reference point of the robot calculated based on the operation program. Here, acceleration and tilt will be described as examples of the physical quantity. The tilt refers to the maximum angle of rotation of the hand coordinate system (xyz) around each of the XYZ axes with respect to the robot coordinate system (XYZ). The physical quantity may be either acceleration or tilt, or both acceleration and tilt. Here, the latter case will be described. Further, the physical quantity may be other physical quantities such as frequency other than acceleration and tilt.

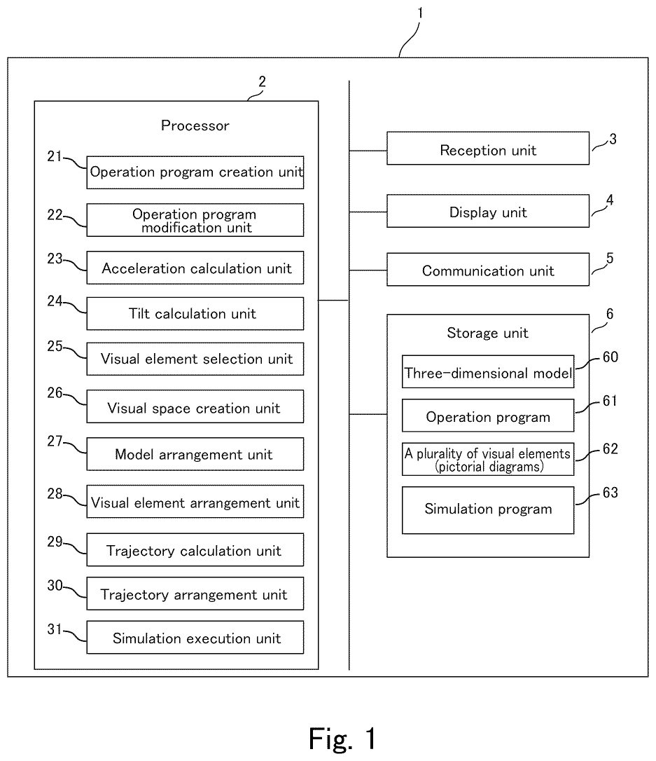

As shown in FIG. 1, a simulation apparatus 1 according to the present embodiment is configured by connecting hardware such as a reception unit 3, a display unit 4, a communication unit 5, and a storage unit 6 to a processor 2 (such as a CPU). The simulation apparatus 1 is provided by a general information processing terminal such as a personal computer or a tablet.

The reception unit 3 receives various parameters relating to an operation program via an input device such as a keyboard, a mouse, or a jog, or directly from an operation program generation unit 21. The parameters relating to the operation program include information relating to the teaching position, information relating to the interpolation format, information relating to the movement format, and information relating to the operation speed. The interpolation format determines what trajectory is used for movement move between two teaching positions. For example, the interpolation format “Joint” means performing circular interpolation between two teaching positions so as not to apply a load to each joint of the robot apparatus. The interpolation format includes other interpolation formats such as linear interpolation. The movement format is a condition relating to how to move the robot apparatus between a plurality of teaching points. For example, the movement format “FINE” means moving the robot apparatus so that it always passes through the teaching points. The movement format “Nameraka” means that the robot apparatus does not necessarily have to pass through the teaching points, but is moved smoothly so as to pass through or near the teaching points. The operation speed is expressed as a percentage of a predefined maximum speed. For example, the operation speed “100%” indicates that each axis of the robot apparatus is moved at the maximum speed.

The display unit 4 includes a display device such as an LCD. The display unit 4 displays a simulation screen. The simulation screen includes a virtual space that represents the operation space of a robot system model. A touch panel or the like that serves as both the reception unit 3 and the display unit 4 may be used.

The communication unit 5 controls transmission and reception of data to and from an external information processing apparatus, such as a robot control apparatus that controls a robot. By the processing of the communication unit 5, an operation program created using the simulation apparatus 1 can be provided to the robot control apparatus.

The storage unit 6 has a storage device such as an HDD or an SSD, and stores various types of information necessary for creating an operation program, information relating to the created operation program 61, information necessary for executing operation simulation of the robot system, and the like. Specifically, the storage unit 6 stores data of a plurality of types of three-dimensional models 60 as information necessary for executing operation simulation of the robot system. For example, the plurality of types of three-dimensional models 60 include a robot model, a workpiece model, and the like. The robot model includes an articulated arm mechanism model and a hand model. Typically, the three-dimensional models 60 are provided by CAD data. Hereinafter, for convenience of explanation, the robot model and the workpiece model may be simply referred to as a robot and a workpiece, respectively.

The storage unit 6 stores graphic data for displaying, on a display as a pictorial diagram, each of a plurality of visual elements 62 for distinguishing the amount of the physical quantity applied to the hand reference point of the robot. As described above, acceleration and tilt are handled here as the physical quantity. Four types of visual elements 62 are provided to distinguish between the result of comparison of acceleration with respect to a threshold value (first threshold value) and the result of comparison of tilt with respect to a threshold value (second threshold value).

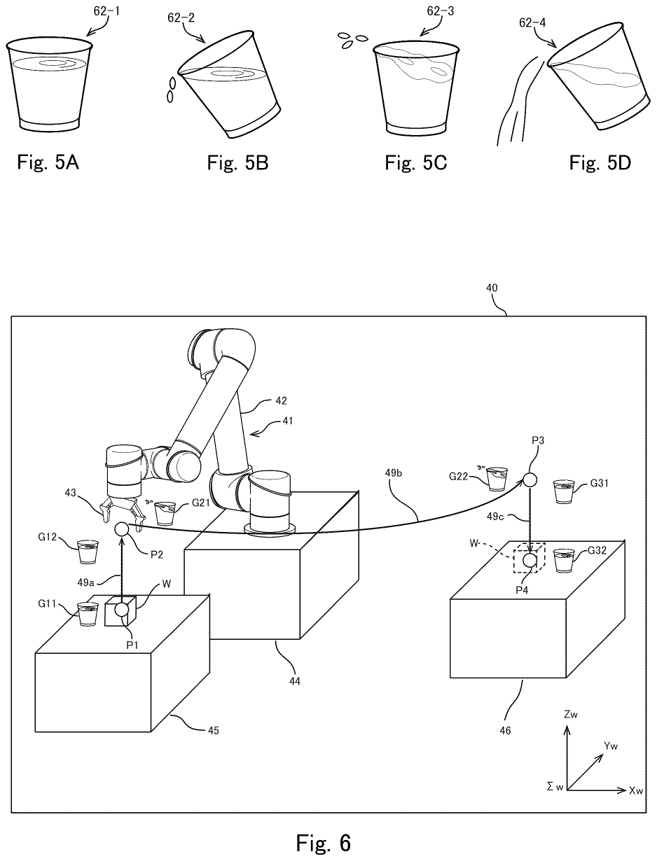

These visual elements 62 share a common object and have forms that differ from each other. FIG. 5A to FIG. 5D illustrate four types of visual elements 62. The object here is “a glass filled with water”. The amount of acceleration is distinguished by the difference in the form of horizontal/inclined of the water surface, and the amount of tilt is distinguished by the difference in the form of upright/laterally tilted of the glass. Specifically, the visual element 62-1 indicates a state in which both the acceleration and the tilt are not excessive, i.e., are less than the respective threshold values (first and second threshold values), and pictorially represents a form in which the water surface is horizontal and the glass is upright. The visual element 62-2 indicates a state in which the acceleration is less than the first threshold value and the tilt is equal to or greater than the second threshold value, and pictorially represents a form in which the water surface is horizontal and the glass is laterally tilted. The visual element 62-3 indicates a state in which the acceleration is equal to or greater than the first threshold value and the tilt is less than the second threshold value, and pictorially represents a form in which the water surface is inclined and the glass is upright. The visual element 62-4 indicates a state in which the acceleration is equal to or greater than the first threshold value and the tilt is equal to or greater than the second threshold value, and pictorially represents a form in which the water surface is inclined and the glass is laterally tilted. Note that the state in which one or both of the acceleration and the tilt are excessive is supplementarily expressed by water overflowing from the glass and the difference in the amount of overflowing water. Note that the storage unit 6 stores data of the threshold value (first threshold value) for distinguishing the magnitude of the acceleration and data of the threshold value (second threshold value) for distinguishing the magnitude of the tilt of the workpiece.

A simulation program is stored in the storage unit 6. When the simulation program is executed by the processor 2, the simulation apparatus 1 functions as an operation program creation unit 21, an operation program modification unit 22, an acceleration calculation unit 23, a tilt calculation unit 24, a visual element selection unit 25, a virtual space creation unit 26, a model arrangement unit 27, a visual element arrangement unit 28, a trajectory calculation unit 29, a trajectory arrangement unit 30, and a simulation execution unit 31.

The operation program creation unit 21 creates an operation program 61 for the robot based on information received via the reception unit 3. The operation program 61 created by the operation program creation unit 21 is stored in the storage unit 6. The operation program 61 includes a position command, a speed command, a motion command (interpolation format, movement format), and the like.

The operation program modification unit 22 modifies the operation program 61. The main methods for modifying the operation program 61 include a method of modifying it in accordance with a user instruction and a method of modifying it automatically in accordance with a predetermined rule. For example, in the automatic modification method, the operation program modification unit 22 modifies the speed command in the operation program 61 so that the magnitude of the acceleration at a specific teaching position decreases. The specific teaching position may be designated by the user, or a teaching position where the magnitude of the acceleration is larger than the first threshold value may be automatically extracted.

The acceleration calculation unit 23 calculates an acceleration (hereinafter simply referred to as an acceleration) applied to the hand reference point of the robot based on the operation program 61. Specifically, the acceleration calculation unit 23 calculates the magnitudes (simply referred to as accelerations) of a plurality of acceleration vectors corresponding to a plurality of teaching positions defined by the operation program 61, based on the operation program 61 created by the operation program creation unit 21. Note that the acceleration may be calculated as the magnitude of an acceleration component of the acceleration vector with respect to any of XYZ axes. For example, when the workpiece stiffness is low with respect to the Z-axis direction, it is preferable to compare the acceleration component with respect to the Z-axis designated by the user with the first threshold value.

The position where the acceleration is calculated is not limited to the teaching position, and can be set at any position on the movement trajectory along which the hand reference point moves from the starting point to the ending point. The acceleration at the teaching position that is the point of change in the moving direction or the speed includes the acceleration at the time of moving from another teaching position to that teaching position and the acceleration at the time of moving from that teaching position to another teaching position.

The tilt calculation unit 24 calculates the tilt of the hand reference point, in other words, the tilt of the workpiece. Specifically, the tilt calculation unit 24 calculates a plurality of tilts corresponding to a plurality of teaching positions defined by the operation program 61, based on the operation program 61 created by the operation program creation unit 21. The tilt is identified as the maximum value of the rotation angle of the hand coordinate system (x, y, z) having the hand reference point as the origin around each axis XYZ with respect to the robot coordinate system (X, Y, Z). Note that the tilt may be a rotation angle around any axis of XYZ. The position where the tilt is calculated is not limited to the teaching position, and can be set at any position on the movement path along which the hand reference point moves from the starting point to the ending point.

The visual element selection unit 25 selects one visual element from four types of visual elements 62-1, 62-2, 62-3, and 62-4 having different forms, based on the acceleration calculated by the acceleration calculation unit 23 and the tilt calculated by the tilt calculation unit 24. Typically, the visual element selection unit 25 selects one visual element from the four types of visual elements 62-1, 62-2, 62-3, and 62-4 in accordance with the combination of the result of comparison of the acceleration with respect to the first threshold value and the result of comparison of the tilt with respect to the second threshold value.

The virtual space creation unit 26 creates a virtual space on software that three-dimensionally represents the operation space of the robot system. The virtual space created by the virtual space creation unit 26 is displayed on the display unit 4.

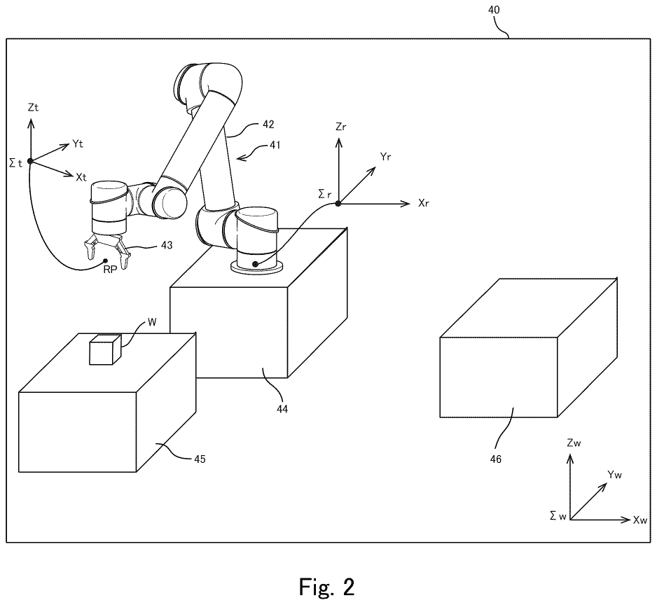

The model arrangement unit 27 arranges the robot model and the workpiece model constituting the robot system model in the virtual space created by the virtual space creation unit 26. The robot model and the workpiece model are arranged in the virtual space so as to correspond to the positional relationship between the robot and the workpiece in the actual operation space. FIG. 2 shows a state in which the robot system model is arranged by the model arrangement unit 27 in the virtual space created by the virtual space creation unit 26. In the virtual space 40, stands 44, 45, and 46 are arranged, with a robot 41 arranged on the stand 44, and a workpiece W arranged on the stand 45. Here, it is assumed that the workpiece W on the stand 45 is held by the robot 41, and the held workpiece W is released onto the stand 46. The robot 41 includes an articulated arm mechanism 42 and a hand 43. The hand 43 has two fingers that can be opened and closed, and a hand reference point RP is set at a central position of the opening and closing. The robot coordinate system Er is an orthogonal coordinate system having the center position of the base of the robot 41 as the origin. The tool coordinate system Et is an orthogonal coordinate system having the hand reference point RP as the origin.

The visual element arrangement unit 28 arranges a visual element 62 selected by the visual element selection unit 25 in the virtual space created by the virtual space creation unit 26. Typically, the visual element arrangement unit 28 arranges the selected visual element 62 at a specific teaching position or at a position corresponding to the specific teaching position, based on the acceleration and tilt calculated for the specific teaching position.

The trajectory calculation unit 29 draws a trajectory of the hand reference point in the virtual space. Specifically, the trajectory calculation unit 29 calculates a trajectory of the hand reference point from the starting point to the ending point, based on the teaching position, the interpolation format, and the movement format defined by the operation program 61.

The trajectory arrangement unit 30 draws the trajectory calculated by the trajectory calculation unit 29 in the virtual space using a line diagram. The thickness of the line diagram is changed stepwise or continuously according to the magnitude of the physical quantity.

The simulation execution unit 31 executes a simulation operation for simulating the operation of the robot system model arranged in the virtual space in accordance with the operation program 61 or in accordance with a user instruction via the operation unit.

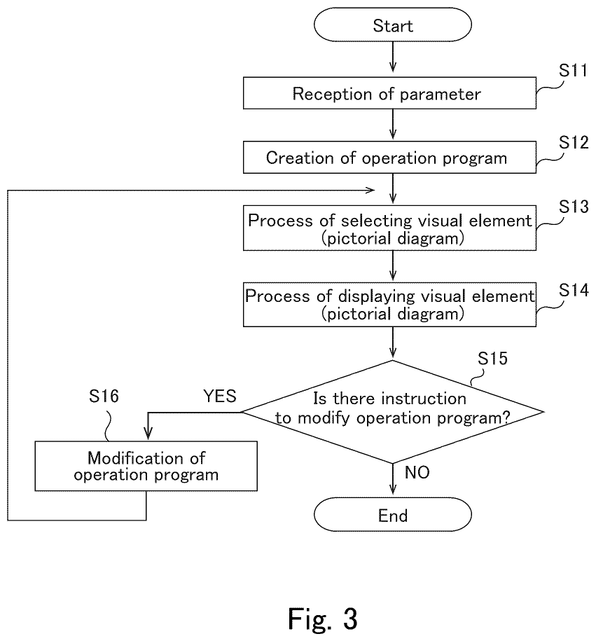

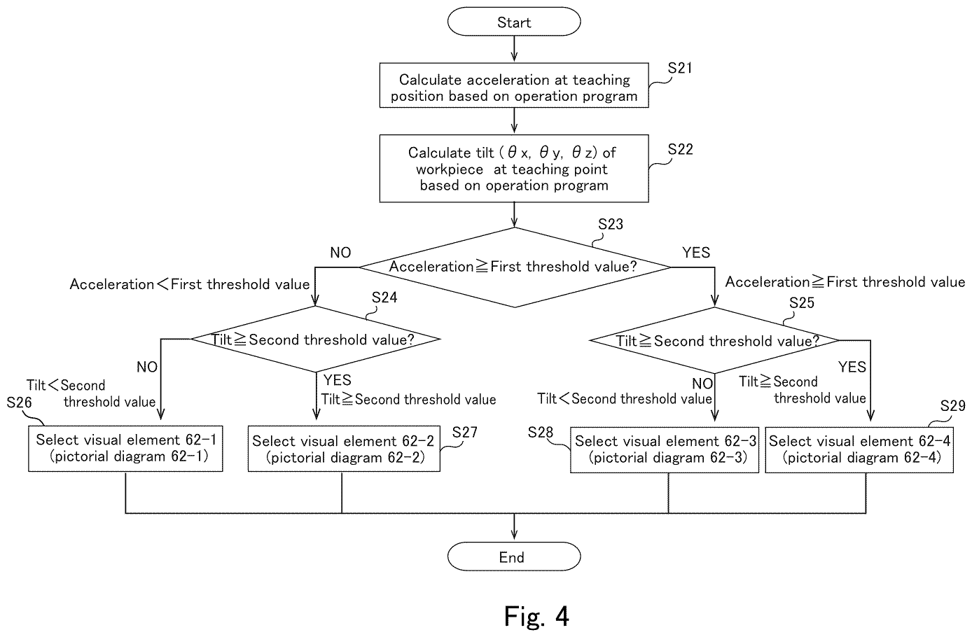

A procedure for creating the operation program 61 using the simulation apparatus 1 according to the present embodiment will be described below with reference to FIG. 3 and FIG. 4. As shown in FIG. 3, when the simulation apparatus 1 receives information necessary for creating the operation program 61 of the robot (S11), the simulation apparatus 1 creates the operation program 61 based on the received information (S12). Then, based on the operation program 61, the simulation apparatus 1 executes a process of selecting a visual element 62 (S13), and displays the selected visual element 62 (S14). The user confirms the visual element 62 displayed on the simulation apparatus 1 and determines whether or not to modify the operation program 61. When the simulation apparatus 1 receives an instruction to modify the operation program 61 through a user operation (S15; YES), the simulation apparatus 1 automatically modifies the operation program 61 (S16), and return the processing to step S13. That is, based on the modified operation program 61, the simulation apparatus 1 automatically executes the process of selecting a visual element 62 in step S13 and the process of displaying the visual element 62 in step S14, and updates the visual element 62 based on the operation program 61 before modification displayed on the simulation apparatus 1 to the visual element 62 based on the operation program 61 after modification. The processes of steps S13, S14, and S16 are repeatedly executed each time an instruction to modify the operation program 61 is received. The modification of the operation program 61 in step S16 may be performed manually by the user. In this manner, the user can confirm the visual element 62 displayed on the display unit 4 of the simulation apparatus 1 according to the present embodiment and create the operation program 61 while indicating modifications as necessary.

FIG. 4 is a flowchart showing an example of the procedure of the process of selecting a visual element 62 in step S13 of FIG. 3. As shown in FIG. 4, the simulation apparatus 1 calculates the acceleration and the tilt at the teaching position based on the created operation program 61 (S21, S22).

When the acceleration calculated in step S21 is smaller than the first threshold value and the tilt calculated in step S22 is smaller than the second threshold value (S23; NO, S24; NO), the simulation apparatus 1 selects the visual element 62-1 shown in FIG. 5A (S26).

When the acceleration calculated in step S21 is smaller than the first threshold value and the tilt calculated in step S22 is equal to or greater than the second threshold value (S23: NO, S24: YES), the simulation apparatus 1 selects the visual element 62-2 shown in FIG. 5B (S27).

When the acceleration calculated in step S21 is equal to or greater than the first threshold value and the tilt calculated in step S22 is smaller than the second threshold value (S23; YES, S25; NO), the simulation apparatus 1 selects the visual element 62-3 shown in FIG. 5C (S28).

When the acceleration calculated in step S21 is equal to or greater than the first threshold value and the tilt calculated in step S22 is equal to or greater than the second threshold value (S23; YES, S25; YES), the simulation apparatus 1 selects the visual element 62-4 shown in FIG. 5D (S29).

The process of selecting a visual element 62 shown in FIG. 5A to FIG. 5D are executed for each of the plurality of teaching positions. A plurality of visual elements 62 corresponding to the plurality of teaching positions can be thereby selected.

The plurality of visual elements 62 selected by the process of step S13 in FIG. 4 are displayed on the display unit 4 by the process of step S14. Typically, the plurality of visual elements 62 are arranged in the virtual space 40 shown in FIG. 2. FIG. 5A to FIG. 5D show examples of a state in which a plurality of visual elements 62 are arranged in the virtual space 40 shown in FIG. 2. As shown in FIG. 5A to FIG. 5D, the plurality of visual elements are arranged at a plurality of teaching positions, respectively. Specifically, the visual elements G11 and G12 represent the accelerations and tilts of the hand reference point of the robot 41 at the teaching positions P1 and P2, respectively, when the workpiece W held by the robot 41 is moved from the teaching position P1 toward the teaching position P2. The visual elements G21 and G22 represent the accelerations of the robot 41 and the tilts of the workpiece W at the teaching positions P2 and P3, respectively, when the workpiece W held by the robot 41 is moved from the teaching position P2 toward the teaching position P3. The visual elements G31 and G32 represent the accelerations of the robot 41 and the tilts of the workpiece W at the teaching positions P3 and P4, respectively, when the workpiece W held by the robot 41 is moved from the teaching position P3 toward the teaching position P4. In addition, in FIG. 5A to FIG. 5D, trajectory models 49 (49a, 49b, 49c) representing trajectories of the hand reference point are arranged. The trajectory model 49a represents the trajectory of the hand reference point from the teaching position P1 toward the teaching position P2. The trajectory model 49b represents the trajectory of the hand reference point from the teaching position P2 toward the teaching position P3. The trajectory model 49c represents the trajectory of the hand reference point from the teaching position P3 toward the teaching position P4.

The simulation apparatus 1 according to the present embodiment can display a visual element that visually reflects the magnitude of the acceleration and the magnitude of the tilt in the virtual space 40 included in the simulation screen as shown in FIG. 5A to FIG. 5D. Accordingly, the user can intuitively grasp the magnitude of the acceleration and the magnitude of the tilt by viewing the displayed visual element. Further, the plurality of visual elements that are display candidates are identical visual elements having different forms so that they can be compared with each other. This ability to compare displayed visual elements with each other further facilitates intuitive grasping of the magnitude of acceleration and the magnitude of the tilt.

In the present embodiment, the user can intuitively recognize the amount of the acceleration and the amount of the tilt by using a “glass filled with water” as the object and selectively using visual elements that represent different forms such as upright/laterally tilted glass, horizontal/inclined water surface, and water overflowing/not overflowing from the glass as pictorial diagrams.

Specifically, the tilt of the workpiece is represented by the tilt of the glass. In general, the top and bottom of a glass can be easily recognized at a glance. As described above, by employing, as a visual element, a glass that allows the user to recognize the top and bottom at a glance, the user can immediately and intuitively grasp the magnitude of the tilt of the workpiece by seeing the tilt of the glass displayed.

In addition, the acceleration of the robot is represented by the state of the water surface of the glass. Normally, when a glass filled with water is moved at a constant speed, the water surface does not ripple. On the other hand, when a glass filled with water is accelerated or decelerated, the water surface ripples. These phenomena are understood by users from their daily experience. As described above, by employing a visual element such as a glass filled with water, which is understood beforehand to have a different form depending on acceleration and deceleration, the user can intuitively and immediately grasp the magnitude of the acceleration of the robot by looking at the state of the water surface of the displayed glass.

The large tilt and the large acceleration of the workpiece are represented by water spilling from the glass. Users experience on a daily basis and understand that water spills when a glass filled with water is tilted, that water spills when a glass filled with water is accelerated or decelerated, and that a large amount of water spills when the glass is tilted or accelerated or decelerated excessively. Furthermore, users understand beforehand that it is not normal but abnormal for water to spill. Accordingly, by expressing water spilling from the glass with the tilt of the glass and the state of the water surface of the glass, the user who sees this can intuitively grasp that the tilt of the workpiece or the acceleration of the robot is excessively large and abnormal, and can be prompted to modify the operation program. In this way, expressing the visual elements by things and phenomena around the user further facilitates intuitive grasp by the user. Further, the visual element is arranged at a position on the trajectory of the hand reference point, for which the acceleration and the tilt were calculated, or at a position corresponding thereto. Accordingly, the user can easily grasp which position the viewed visual element corresponds to, and can immediately grasp at which position the operation has a problem.

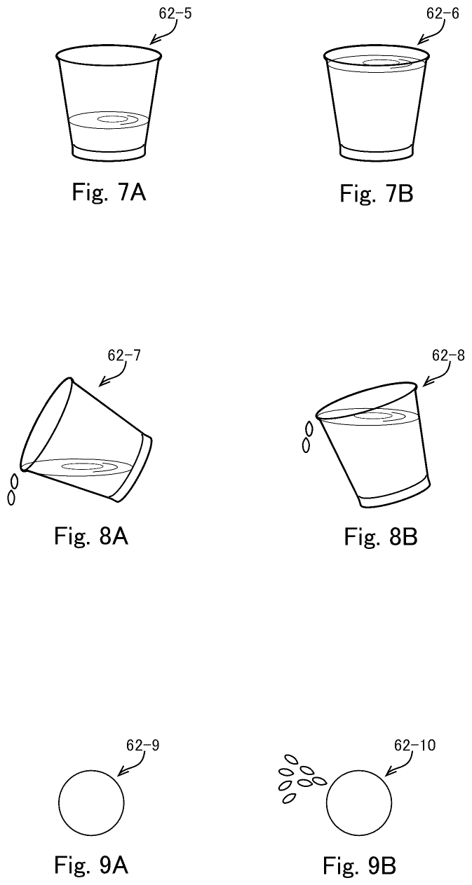

In the present embodiment, the visual element 62 is a pictorial diagram that distinguishes the amount of the acceleration and the amount of the tilt, but may further reflect the magnitude of the first threshold value for judging the magnitude of the acceleration. As shown in FIG. 7A and FIG. 7B, for example, the magnitude of the first threshold value can be represented by the height of the water surface of the water in the glass. The height of the water surface in the glass represented by the visual element 62-5 in FIG. 7A is lower than the height of the water surface in the glass represented by the visual element 62-6 in FIG. 7B. The higher the water surface, the more likely the water in the glass spills. That is, the visual element 62-6 shown in FIG. 7B indicates that the first threshold value is more severe, in other words, the first threshold value is smaller, than that of the visual element 62-5 shown in FIG. 7A, which means that even a small acceleration may affect the workpiece.

The visual element 62 may also reflect the magnitude of the second threshold value for judging the magnitude of the tilt. As shown in FIG. 8A and FIG. 8B, the magnitude of the second threshold value can be represented by the tilt of the glass. The tilt of the glass shown in FIG. 8A is larger than the tilt of the glass shown in FIG. 8B. The more the glass is tilted, the more likely the water in the glass spills. That is, the visual element 62-7 shown in FIG. 8A indicates that the second threshold value is more severe, in other words, the second threshold value is smaller, than that of the visual element 62-8 shown in FIG. 8B, which means that even a small tilt may affect the workpiece.

In the present embodiment, a plurality of visual elements 62 that simultaneously reflect the magnitude of the acceleration of the robot and the magnitude of the tilt of the workpiece are prepared, and one visual element 62 is selected from the plurality of visual elements 62 based on the acceleration of the robot and the tilt of the workpiece at the teaching position. By viewing the visual element 62, the user can simultaneously confirm whether the workpiece is not subjected to a large inertial load caused by the acceleration and deceleration of the robot and whether the held workpiece is moved without excessive tilting. However, if the user wants to confirm only whether the robot is accelerating or decelerating in a way that generates a large inertial load, it is possible to prepare a plurality of visual elements that reflect only the magnitude of the acceleration of the robot, and select one visual element from the plurality of visual elements based on the acceleration of the robot. Similarly, if the user wants to confirm only the change in the tilt of the workpiece after holding, it is possible to prepare a plurality of visual elements that reflect only the magnitude of the tilt of the workpiece, and select one visual element from the plurality of visual elements based on the tilt of the workpiece.

In the present embodiment, the visual element 62 simultaneously reflects the magnitude of the acceleration of the robot and the magnitude of the tilt of the workpiece, and one visual element 62 is arranged at the teaching position. However, a plurality of visual elements may be arranged at the teaching position. For example, it is possible to prepare a plurality of first visual elements that reflect only the magnitude of the acceleration and a plurality of second visual elements that reflect only the magnitude of the tilt, select one first visual element from the plurality of first visual elements based on the acceleration at the teaching position, select one second visual element from the plurality of second visual elements based on the tilt, and arrange two types of visual elements, i.e., the first and second visual elements, for the teaching position.

One object of the embodiment of the present invention is to allow users to intuitively grasp physical quantities relating to the operation of the robot. In the present embodiment, the acceleration of the robot and the tilt of the workpiece are adopted as examples of the physical quantities in order to confirm whether the workpiece is maintained horizontally and whether there is no acceleration or deceleration that provides a large inertial load to the workpiece. The type of physical quantity can be based on what the user wants to confirm. For example, if the user wants to confirm whether the robot is not operating at a speed that may lead to a serious injury to the user, it is possible to use the speed as the physical quantity and prepare a plurality of visual elements that reflect the magnitude of the speed, select one visual element from the plurality of visual elements based on the speed at the teaching position, and display the selected visual element. Further, in the case where the tilt of the hand is an issue, it is possible to use the tilt of the hand as the physical quantity and prepare a plurality of visual elements that reflect the magnitude of the tilt of the hand, select one visual element from the plurality of visual elements based on the tilt of the hand at the teaching position, and display the selected visual element.

In the present embodiment, in order to allow users to intuitively grasp the magnitude of the acceleration of the robot and the magnitude of the tilt of the workpiece, a glass filled with water is adopted as the visual element 62 capable of simultaneously reflecting the magnitude of the acceleration of the robot and the magnitude of the tilt of the workpiece. However, the visual element 62 is not limited to this. Further, if only the magnitude of the acceleration of the robot or the magnitude of the tilt of the workpiece is to be reflected, simpler visual elements can be used. For example, as shown in FIG. 9A and FIG. 9B, a simple circular visual element can be adopted as the visual element that reflects only the magnitude of the acceleration of the robot. The visual element 62-9 in FIG. 9A represents the form when the acceleration is less than the first threshold value, and the visual element 62-10 in FIG. 9B represents the form when the acceleration is equal to or greater than the first threshold value. The visual element 62-10 in FIG. 9B represents water splashing from the circular visual element. This splash represents the glass being shaken so much that the water in the glass splashes out of the glass with force. By viewing the visual element 62-10 shown in FIG. 9B, the user can intuitively grasp that the acceleration is equal to or greater than the first threshold value.

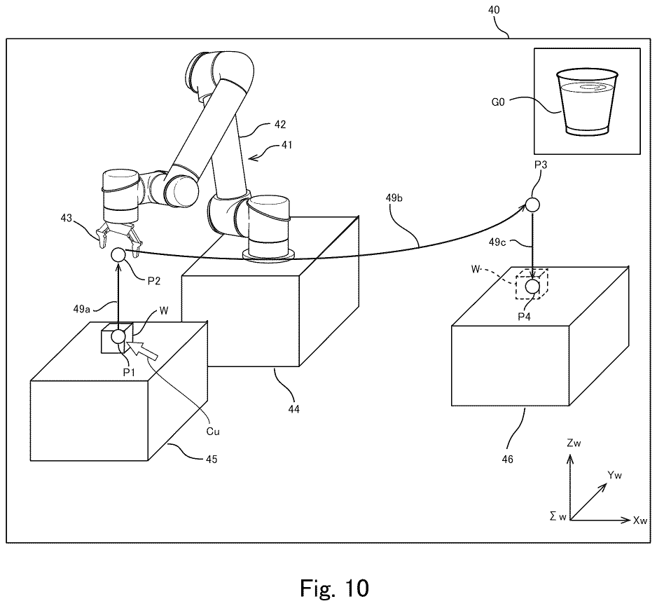

In the present embodiment, the visual element 62 selected based on the acceleration and tilt at a specific teaching position is arranged at the specific teaching position or at a position corresponding to the specific teaching position in the virtual space. However, the method of displaying the visual element 62 is not limited to this as long as the user can grasp the correspondence between the position and the visual element 62. For example, as shown in FIG. 10, the visual element GO may be always displayed at a specific position of the display unit 4, and the display form of the visual element GO may be changed in conjunction with user operation in the virtual space 40. For example, when a cursor Cu is positioned at a teaching position P1 by a user operation, the visual element GO changes to the form of the visual element corresponding to the teaching position P1, and when the cursor Cu is positioned at a teaching position P2, it changes to the form of the visual element corresponding to the teaching position P2. Such a method of displaying the visual element also has the same effect as the method of displaying the visual element at the teaching position or at a position corresponding to the teaching position.

One feature of the simulation apparatus 1 according to the present embodiment is that it calculates an acceleration and a tilt based on an operation program, and selects and displays a visual element corresponding to the calculated acceleration and tilt from a plurality of visual elements. Accordingly, the reception unit 3 does not need to have a function of receiving parameters relating to an operation program and creating the operation program, and may receive the operation program itself from the outside.

Although several embodiments of the present invention have been described, these embodiments are presented by way of example and are not intended to limit the scope of the invention. These embodiments can be implemented in various other forms, and various omissions, replacements, and changes can be made without departing from the spirit of the invention. These embodiments and their modifications are included in the scope and spirit of the invention and are included in the scope of the claimed inventions and their equivalents.

1. A simulation apparatus for causing a three-dimensional model representing a robot to operate in a virtual space in accordance with an operation program for causing the robot to operate, the simulation apparatus comprising:
a reception unit configured to receive an input of a parameter relating to the operation program;
a physical quantity calculation unit configured to calculate, based on the parameter, a physical quantity applied to a reference point of the robot; and
a display unit configured to display the three-dimensional model and one visual element selected, based on the physical quantity, from a plurality of visual elements.

2. The simulation apparatus according to claim 1, wherein the visual elements are pictorial diagrams of a common object in different forms.

3. The simulation apparatus according to claim 1, wherein at least one of an acceleration of the reference point and a tilt of a coordinate system having the reference point as an origin with respect to a robot coordinate system is calculated as the physical quantity.

4. The simulation apparatus according to claim 3, wherein the visual element is a pictorial diagram of a glass containing water.

5. The simulation apparatus according to claim 4, wherein the plurality of visual elements include a first visual element pictorially representing a state in which the acceleration is equal to or greater than a threshold value and a second visual element pictorially representing a state in which the acceleration is less than the threshold value.

6. The simulation apparatus according to claim 5, wherein
the first visual element is a pictorial diagram representing a state in which a water surface of the water in the glass is inclined or a state in which the water is overflowing, and
the second visual element is a pictorial diagram representing a state in which the water surface of the water in the glass is horizontal.

7. The simulation apparatus according to claim 4, wherein the visual elements include a first visual element pictorially representing a state in which the tilt is equal to or greater than a threshold value and a second visual element pictorially representing a state in which the tilt is less than the threshold value.

8. The simulation apparatus according to claim 7, wherein
the first visual element is a pictorial diagram representing a state in which the glass is laterally tilted or a state in which the water is overflowing, and
the second visual element is a pictorial diagram representing a state in which the glass is horizontal.

9. The simulation apparatus according to claim 1, further comprising a selection unit configured to select the one visual element from the plurality of visual elements, based on a result of comparison of the physical quantity with one or more threshold values.

10. The simulation apparatus according to claim 1, wherein
the physical quantity calculation unit calculates the physical quantity at each of a plurality of positions on a movement trajectory of the reference point of the robot based on the parameter, and
the display unit displays a virtual operation space including the three-dimensional model of the robot, and displays visual elements selected for the plurality of positions at positions corresponding to the plurality of positions in the virtual operation space.

11. The simulation apparatus according to claim 1, further comprising a trajectory calculation unit configured to calculate a trajectory of the reference point based on the parameter, wherein the display unit displays a virtual space including the three-dimensional model of the robot and displays a line diagram representing the trajectory in the virtual space.

12. The simulation apparatus according to claim 11, wherein a thickness of the line diagram is changed in accordance with a magnitude of the physical quantity.
